(19) United States
(12) Patent Application Publication
(10) Pub. No.: US 2025/0337370 A1
(43) Pub. Date: Oct. 30, 2025

(54) ADJUSTMENT CIRCUIT

(71) Applicant: SMARTER MICROELECTRONICS (GUANG ZHOU) CO., LTD., Guangzhou (CN)

(72) Inventors: Yang HOU, Guangzhou (CN); Jun JIA, Guangzhou (CN)

(73) Assignee: SMARTER MICROELECTRONICS (GUANG ZHOU) CO., LTD., Guangzhou (CN)

(21) Appl. No.: 19/017,642

(22) Filed: Jan. 11, 2025

(30) Foreign Application Priority Data
Apr. 26, 2024 (CN) 202410514287.3

(51) Int. Cl. H03F 1/56; H03F 3/24

(52) U.S. Cl. CPC H03F 1/565; H03F 3/245; H03F 2200/387; H03F 2200/451

(57) ABSTRACT

An adjustment circuit, which is connected to an output of a Power Amplifier (PA), includes a sampling circuit, a detector circuit, an impedance adjustment circuit, and an aperture tuning circuit. The sampling circuit is connected to the output of the PA, and is configured to sample a transmission signal and a reflection signal from the output of the PA, and output the sampled transmission signal and reflection signal. The detector circuit is coupled to an output of the sampling circuit, and is configured to acquire the sampled transmission signal and reflection signal, and output a first detection signal according to amplitudes of the sampled transmission signal and the sampled reflection signal. The impedance adjustment circuit is connected to the detector circuit, and is configured to adjust impedance according to the first detection signal, to reduce the reflection signal. The aperture tuning circuit is connected to the impedance adjustment circuit.

### CROSS-REFERENCE TO RELATED APPLICATION

The present application claims priority to Chinese Patent Application No. 202410514287.3 filed on Apr. 26, 2024, the disclosure of which is hereby incorporated by reference in its entirety.

### BACKGROUND

In a mobile Radio Frequency (RF) terminal, matching between a Transmit-Receive (TR) module and an antenna greatly affects performance of the terminal, and the TR module mainly includes a transmission Power Amplifier (PA) and a receiver Low Noise Amplifier (LNA). In an actual application scenario, impedance of the antenna changes due to environmental effect, which is reflected as poor signal, increased power consumption, or the like in terms of user experience.

### SUMMARY

In view of this, embodiments of the disclosure provide an adjustment circuit.

The disclosure relates to the field of electronic technologies, and in particular to an adjustment circuit.

An embodiment of the disclosure provides an adjustment circuit, the adjustment circuit is connected to an output of a PA, and includes a sampling circuit, a detector circuit, an impedance adjustment circuit, and an aperture tuning circuit. The sampling circuit is connected to the output of the PA, and is configured to sample a transmission signal and a reflection signal from the output of the PA, and output the sampled transmission signal and the sampled reflection signal. The detector circuit is coupled to an output of the sampling circuit, and is configured to acquire the sampled transmission signal and the sampled reflection signal, and output a first detection signal according to an amplitude of the sampled transmission signal and an amplitude of the sampled reflection signal. The impedance adjustment circuit is connected to the detector circuit, and is configured to adjust impedance according to the first detection signal, to reduce the reflection signal. The aperture tuning circuit is connected to the impedance adjustment circuit.

In some embodiments, the detector circuit may include a first comparator. The first comparator is provided with a first end connected to the sampling circuit and receiving the sampled transmission signal, and a second end connected to the sampling circuit and receiving the sampled reflection signal. The first comparator is configured to compare the amplitude of the sampled transmission signal with the amplitude of the sampled reflection signal and output the first detection signal.

In some embodiments, the impedance adjustment circuit may be configured to: turn on or off adjustment of the impedance according to the first detection signal, and adjust the impedance according to the first detection signal.

In some embodiments, when the first detection signal is less than or equal to a preset value, the impedance adjustment circuit may turn on adjustment of the impedance and adjust the impedance, and when the first detection signal is greater than the preset value, the impedance adjustment circuit may turn off adjustment of the impedance. Or, when the first detection signal is equal to or greater than a preset value, the impedance adjustment circuit may turn on adjustment of the impedance and adjust the impedance, and when the first detection signal is less than the preset value, the impedance adjustment circuit may turn off adjustment of the impedance.

In some embodiments, the detector circuit may further include a second comparator. The second comparator is provided with a first end connected to an output of the first comparator and receiving the first detection signal, and a second end receiving a reference signal. The second comparator is configured to compare the reference signal with the first detection signal and output a second detection signal, and the second comparison signal is configured to turn on or off adjustment of the impedance performed by the impedance adjustment circuit.

In some embodiments, when the first detection signal is less than or equal to the reference signal, the impedance adjustment circuit may turn on adjustment of the impedance according to the second detection signal, and adjust the impedance according to the first detection signal; when the first detection signal is greater than the reference signal, the impedance adjustment circuit may turn off adjustment of the impedance.

In some embodiments, the impedance adjustment circuit may preset multiple impedance combinations, and the impedance adjustment circuit adjusts the impedance by traversal and/or table lookup.

In some embodiments, the detector circuit may include a first detection circuit and/or a second detection circuit. The first detection circuit is provided with an input coupled to the output of the sampling circuit and receiving the sampled transmission signal, and is configured to rectify the sampled transmission signal, and is provided with an output coupled to the first comparator. The second detection circuit is provided with an input coupled to the output of the sampling circuit and receiving the sampled reflection signal, and is configured to detect the sampled reflection signal, and is provided with an output coupled to the first comparator. The first comparator compares the amplitude of the sampled transmission signal or the detected sampled transmission signal with the amplitude of the sampled reflection signal or the detected sampled reflection signal.

In some embodiments, the detector circuit may include a first amplifier and/or a second amplifier. The first amplifier is coupled to the output of the sampling circuit, receives the sampled transmission signal, is configured to amplify the sampled transmission signal, and is provided with an output coupled to the first comparator. The second amplifier is coupled to the output of the sampling circuit, receives the sampled reflection signal, is configured to amplify the sampled reflection signal, and is provided with an output coupled to the first comparator. The first comparator compares the amplitude of the sampled transmission signal or the amplified sampled transmission signal with the amplitude of the sampled reflection signal or the amplified sampled reflection signal.

In some embodiments, parameters of the first amplifier and/or the second amplifier may be adjustable.

In some embodiments, the impedance adjustment circuit may include a first branch, a second branch, and a third branch. The first branch is provided with a first end connected to the sampling circuit, and a second end which is grounded. The second branch is provided with a first end connected to the aperture tuning circuit, and a second end which is grounded. The third branch is provided with a first end and a second end connected to the first end of the first branch and the first end of the second branch respectively.

In some embodiments, at least one of the first branch, the second branch or the third branch may be provided with multiple inductors and/or capacitors connected in parallel, and a switch is connected in series with at least one path of the parallel circuit.

In some embodiments, the impedance adjustment circuit and the aperture tuning circuit may be integrated into the same module.

In the embodiments of the disclosure, the adjustment circuit detects a state whether an output impedance of the PA is mismatched, including adjustment of the aperture tuning circuit and the impedance adjustment circuit, to tune aperture matching and impedance matching, optimize matching of the output impedance of the PA, and improve radiation efficiency of the transmission signal of the PA.

### BRIEF DESCRIPTION OF THE DRAWINGS

FIG. 1 is a first embodiment of a terminal device provided in the embodiments of the disclosure.

FIG. 2 is a second embodiment of the terminal device provided in the embodiments of the disclosure.

FIG. 3 is a first embodiment of an adjustment circuit provided in the embodiments of the disclosure.

FIG. 4 is a second embodiment of the adjustment circuit provided in the embodiments of the disclosure.

FIG. 5 is a third embodiment of the adjustment circuit provided in the embodiments of the disclosure.

FIG. 6 is a fourth embodiment of the adjustment circuit provided in the embodiments of the disclosure.

FIG. 7 is a fifth embodiment of the adjustment circuit provided in the embodiments of the disclosure.

FIG. 8 is a sixth embodiment of the adjustment circuit provided in the embodiments of the disclosure.

FIG. 9 is a seventh embodiment of the adjustment circuit provided in the embodiments of the disclosure.

FIG. 10 is an eighth embodiment of the adjustment circuit provided in the embodiments of the disclosure.

FIG. 11 is a ninth embodiment of the adjustment circuit provided in the embodiments of the disclosure.

FIG. 12 is a tenth embodiment of the adjustment circuit provided in the embodiments of the disclosure.

FIG. 13 is an eleventh embodiment of the adjustment circuit provided in the embodiments of the disclosure.

FIG. 14 is a twelfth embodiment of the adjustment circuit provided in the embodiments of the disclosure.

### DETAILED DESCRIPTION

The disclosure will be further described in detail below with reference to the drawings and embodiments. It should be understood that specific embodiments described below in the disclosure are only intended to explain the disclosure and are not intended to limit the disclosure.

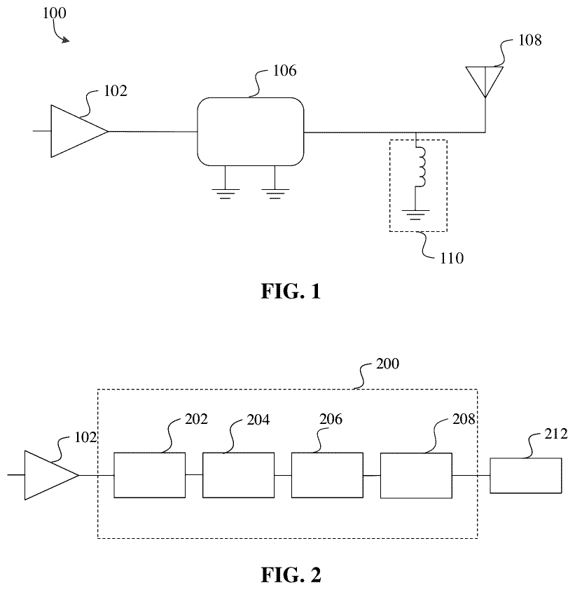

FIG. 1 is a first embodiment of a terminal device provided in the embodiments of the disclosure. With reference to FIG. 1, the terminal device 100 includes a Power Amplifier (PA) 102, an adjustment circuit 106, and an antenna 108 connected in sequence; an output signal from an output of the PA 102 is transmitted to the antenna 108 through the adjustment circuit 106. The adjustment circuit 106 includes an impedance adjustment circuit and an aperture tuning circuit, and is configured to adjust impedance when impedance of the antenna 108 is affected, thereby reducing a reflection signal of the PA 102; for example, the impedance adjustment circuit and/or the aperture tuning circuit are adjusted in real time or at a fixed time, to improve mismatch.

In this embodiment, the terminal device 100 further includes an Electro-Static Discharge (ESD) 110. The ESD may also be omitted in other embodiments.

In some embodiments, the antenna may also be omitted.

In the disclosure, by detecting mismatch state of a path, it enables the adjustment circuit 106 to adjust the impedance, for example, tune aperture matching and impedance matching in real time or at a fixed time, to optimize radiation efficiency of the antenna 108 and matching between the antenna 108 and the PA 102, thereby improving Radio Frequency (RF) performance and user experience of the terminal device 100.

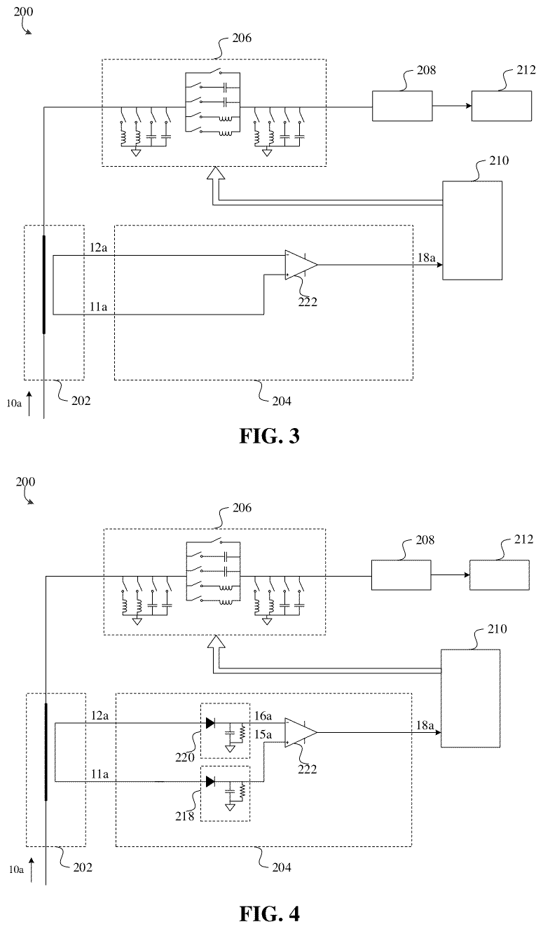

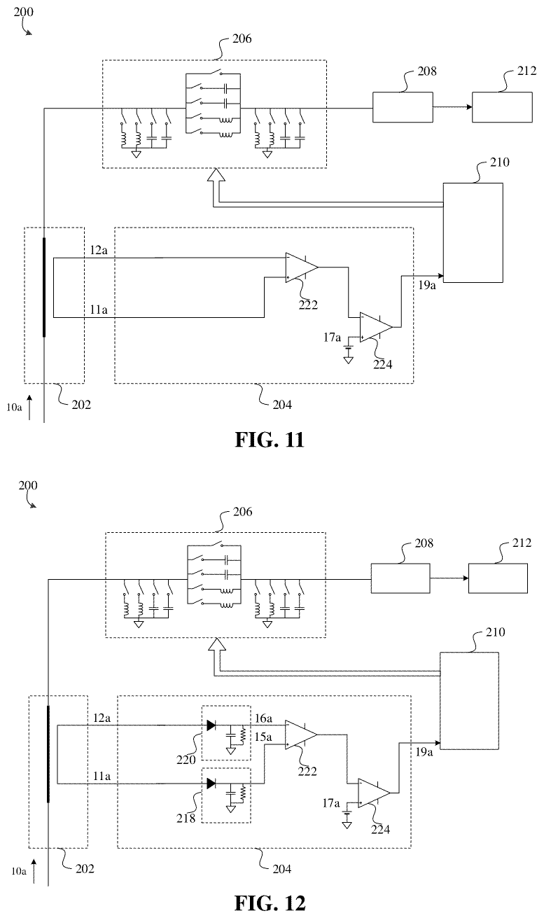

In some embodiments of the disclosure, with reference to FIG. 2, an adjustment circuit 200 is provided, the adjustment circuit 200 is connected to the output of the PA 102, and includes a sampling circuit 202, a detector circuit 204, an impedance adjustment circuit 206, and an aperture tuning circuit 208. The sampling circuit 202 is connected to the output of the PA, and is configured to sample a transmission signal and a reflection signal from the output of the PA, and output the sampled transmission signal and the sampled reflection signal. The detector circuit 204 is coupled to an output of the sampling circuit 202, and is configured to acquire the sampled transmission signal and the sampled reflection signal, and output a first detection signal according to an amplitude of the sampled transmission signal and an amplitude of the sampled reflection signal. The impedance adjustment circuit 206 is connected to the detector circuit 204, and is configured to adjust impedance according to the first detection signal, to reduce the reflection signal. The aperture tuning circuit 208 is connected to the impedance adjustment circuit 206. In some embodiments, the output signal from the output of the PA 102 (it may be understood as an output signal 10a in FIG. 3 to FIG. 14) may be a RF signal. In some embodiments, an antenna 212 may also be omitted.

When impedance of the path is mismatched, the impedance may be adjusted by the impedance adjustment circuit 206; or, the impedance may be adjusted by the impedance adjustment circuit 206 and the aperture tuning circuit 208 together, to enable the mismatched impedance to be matched again, so that the impedance may be dynamically adjusted, thereby reducing the reflection signal and improving the antenna efficiency. Adjustment of the impedance adjustment circuit and adjustment of the aperture tuning circuit are not divided into primary adjustment and secondary adjustment, and each of the two adjustments may be primary adjustment; or, one of the two adjustments may be primary adjustment, and another one of the two adjustments may be fine adjustment, which is not limited here. It should be noted that when bands are switched, the impedance may also be adjusted by the adjustment circuit 200, to make it applicable to different bands.

It should be noted that the aperture tuning circuit may perform adjustment according to an output signal from the sampling circuit and/or the detector circuit, that is, the aperture tuning circuit may perform adjustment according to the sampling signal or the detection signal, which is not limited here.

In some embodiments, with reference to FIG. 3 to FIG. 14, the sampling circuit 202 includes a coupler, the coupler is connected to the output of the PA, samples the transmission signal and the reflection signal from the output of the PA, and outputs the sampled transmission signal 11a and the sampled reflection signal 12a. A number of couplers may be selected according to requirements, and the two signals may be acquired by one coupler or two couplers. It should be noted that sampling parameters of the couplers may be the same or different, which is not limited here. For example, a coupling degree of the transmission signal may be the same as or different from that of the reflection signal. For another example, the coupling degree of the reflection signal is greater than that of the transmission signal.

In some embodiments, with reference to FIG. 3 to FIG. 14, the detector circuit 204 receives the sampled transmission signal 11a and the sampled reflection signal 12a, compares an amplitude of the sampled transmission signal 11a with an amplitude of the sampled reflection signal 12a, and outputs a first detection signal 18a; the first detection signal 18a is configured to determine whether the impedance is mismatched.

In some embodiments, the first detection signal 18a is configured to turn on adjustment of the impedance performed by the impedance adjustment circuit 206 and adjust the impedance, and is also configured to turn off adjustment of the impedance performed by the impedance adjustment circuit 206. In other embodiments, the impedance may also be adjusted by the first detection signal only, and on or off of the impedance adjustment circuit is controlled by other signals.

In some embodiments, with reference to FIG. 3 to FIG. 6, the detector circuit 204 includes a first comparator 222. The first comparator 222 is provided with a first end connected to the sampling circuit 202 and receiving the sampled transmission signal 11a, and a second end connected to the sampling circuit 202 and receiving the sampled reflection signal 12a. The first comparator 222 is configured to compare the amplitude of the sampled transmission signal 11a with the amplitude of the sampled reflection signal 12a and output the first detection signal 18a.

In some embodiments, when the first detection signal 18a is less than or equal to a preset value, the impedance adjustment circuit 206 turns on adjustment of the impedance and adjust the impedance, and when the first detection signal 18a is greater than the preset value, the impedance adjustment circuit 206 turns off adjustment of the impedance. That is, when the first detection signal is less than or equal to the preset value, transmission impedance is mismatched; when the first detection signal is greater than the preset value, it is unnecessary to adjust the transmission impedance. It should be noted that when whether there is mismatch is determined by the first detection signal, it is set according to structures of the first comparator; or, the mismatch may be determined when the first detection signal is equal to or greater than the preset value, and it is unnecessary to adjust the transmission impedance when the first detection signal is less than the preset value.

In some embodiments, the first detection signal 18a is a voltage difference between the sampled transmission signal 11a and the sampled reflection signal 12a, or a ratio of the sampled transmission signal 11a to the sampled reflection signal 12a.

In some embodiments, the preset value is set according to a Voltage Standing Wave Ratio (VSWR). There may be one preset value, or more preset values may be included, to be selected according to different situations.

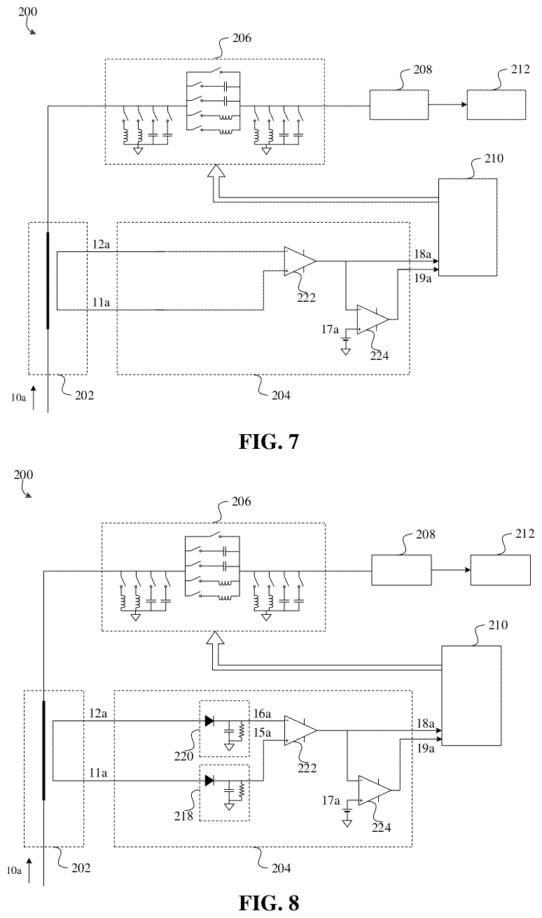

In some embodiments, with reference to FIG. 7 to FIG. 10 and FIG. 11 to FIG. 14, the detector circuit 204 further includes a second comparator 224. The second comparator 224 is provided with a first end connected to an output of the first comparator 222 and receiving the first detection signal 18a, and a second end receiving a reference signal 17a. The second comparator 224 is configured to compare the reference signal 17a with the first detection signal 18a and output a second detection signal 19a, and the second comparison signal 19a is configured to turn on or off adjustment of the impedance performed by the impedance adjustment circuit 206. At this time, the impedance adjustment circuit is configured to adjust the impedance according to the first detection signal. In this way, adjustment of the impedance performed by the impedance adjustment circuit is turned on or off by the second detection signal, so that signal processing may be simplified, and it is unnecessary to process the first detection signal when it is unnecessary to adjust the impedance.

In some embodiments, when the first detection signal 18a is less than or equal to the reference signal 17a, the impedance adjustment circuit 206 turns on adjustment of the impedance according to the second detection signal 19a, and adjusts the impedance according to the first detection signal 18a; according to the first detection signal 18a being greater than the reference signal 17a, the impedance adjustment circuit 206 turns off adjustment of the impedance and stops receiving the first detection signal 18a.

In some embodiments, the second detection signal 19a includes a high level and a low level, to control on or off of the impedance adjustment circuit.

In some embodiments, the reference signal 17a is set according to VSWR, and the reference signal may also include one or more values, which are the same as the preset value and are not elaborated here. It should be noted that the value of the reference signal may be the same as that of the preset value; in some embodiments, the value of the reference signal may also be different from that of the preset value.

In some embodiments, the impedance adjustment circuit 206 presets multiple impedance combinations, and the impedance adjustment circuit 206 adjusts the impedance by traversal and/or table lookup. Table lookup or traversal information includes information of multiple preset impedance combinations of the impedance adjustment circuit 206.

In some embodiments, the table lookup and traversal may be performed simultaneously or separately; and the two adjustment manners may perform primary adjustment on the impedance, or may perform fine adjustment on the impedance, or the fine adjustment may not be required. For example, the impedance adjustment circuit performs the primary adjustment by traversal, and then performs the fine adjustment by table lookup; for another example, the impedance adjustment circuit performs the primary adjustment by table lookup, and then performs the fine adjustment by traversal; for another example, the primary adjustment and the fine adjustment are performed by traversal or table lookup; for another example, the adjustment is performed by traversal or table lookup.

In some embodiments, when mismatch of the transmission impedance is determined according to the second detection signal, the impedance adjustment circuit 206 turns on adjustment of the impedance and adjusts the impedance according to the first detection signal and a Look-Up-Table (LUT) from the table lookup information. The LUT includes information of multiple preset impedance combinations of the impedance adjustment circuit 206 and information of mismatched impedance, and a suitable impedance combination is selected according to the information of mismatched impedance.

In some embodiments, when the impedance is adjusted by traversal, the impedance adjustment circuit 206 is adjusted to the preset impedance combinations in sequence, and after each adjustment, a situation whether the output impedance of the PA is mismatched is determined, until the second detection signal is in a non-mismatch range, and adjustment of the impedance adjustment circuit 206 is stopped.

In some embodiments, the impedance adjustment circuit includes six to twelve impedance combinations, and the mismatched impedance in a range of VSWR 3:1 to 10:1 may be adjusted to be less than VSWR 2.5:1 through adjustment of the impedance. For example, the impedance adjustment circuit includes eight impedance combinations; for another example, the mismatched impedance is adjusted to be VSWR 1.5:1, 2:1, etc.

In some embodiments, the impedance combinations may correspond to designated information bands respectively, for example, each of high/medium/low frequencies has at least three impedance combinations.

In some embodiments, the impedance adjustment circuit includes a first branch, a second branch, and a third branch. The first branch is provided with a first end connected to the sampling circuit, and a second end which is grounded. The second branch is provided with a first end connected to the aperture tuning circuit, and a second end which is grounded. The third branch is provided with a first end and a second end connected to the first end of the first branch and the first end of the second branch respectively.

In some embodiments, at least one of the first branch, the second branch or the third branch is provided with multiple inductors and/or capacitors connected in parallel, and a switch is connected in series with at least one path of the parallel circuit. For example, as shown in FIG. 3, each of the first branch, the second branch and the third branch includes two inductors connected in parallel and two capacitors connected in parallel, and each parallel component is connected in series with a switch, so that it may be adjusted.

In some embodiments, the impedance adjustment circuit includes one or more x-type three-element impedance matching circuits, which may also be understood as the impedance adjustment circuit including a single-stage or multi-stage matching impedance. In some embodiments, each x-type three-element impedance matching circuit may be formed of one inductor and two capacitors, or, of one capacitor and two inductors.

In some embodiments, the inductor in each impedance matching circuit may be set as an adjustable inductor, and/or, the capacitor in each impedance matching circuit may be set as an adjustable capacitor, to enable the impedance matching circuit to adjust impedance conversion according to different RF signals. For example, impedance conversion adjustment may be performed on signals in different bands.

In some embodiments, the detector circuit includes a first detection circuit and/or a second detection circuit. The first detection circuit is provided with an input coupled to the output of the sampling circuit and receiving the sampled transmission signal, and is configured to rectify the sampled transmission signal 11a, and is provided with an output coupled to the first comparator. The second detection circuit is provided with an input coupled to the output of the sampling circuit and receiving the sampled reflection signal, and is configured to detect the sampled reflection signal, and is provided with an output coupled to the first comparator. At this time, the sampling circuit is connected to the first comparator through the first detection circuit and/or the second detection circuit.

In some embodiments, the detector circuit 204 includes a first detection circuit 218, the first detection circuit 218 is configured to detect the sampled transmission signal 11a, the detected sampled transmission signal (hereinafter, it is referred to as a first detection signal 15a, and refers to FIG. 4, FIG. 8 or FIG. 12) is transmitted to the first end of the first comparator 222, and the sampled reflection signal 12a is transmitted to the second end of the first comparator 222 (not shown in FIG. 4, FIG. 8 or FIG. 12).

In some embodiments, the detector circuit 204 includes a second detection circuit 220, the sampled transmission signal 11a is transmitted to the first end of the first comparator 222 (not shown in FIG. 4, FIG. 8 or FIG. 12), the second detection circuit 220 is configured to detect the sampled reflection signal 21a, and the detected sampled reflection signal (hereinafter, it is referred to as a second detection signal 16a, and refers to FIG. 4, FIG. 8 or FIG. 12) is transmitted to the second end of the first comparator 222.

In some embodiments, with reference to FIG. 4, FIG. 8 or FIG. 12, the detector circuit 204 includes a first detection circuit 218 and a second detection circuit 220. The first detection circuit 218 is configured to detect the sampled transmission signal 11a, and the detected sampled transmission signal (hereinafter, it is referred to as a first detection signal 15a) is transmitted to the first end of the first comparator 222. The second detection circuit 220 is configured to detect the sampled reflection signal 21a, and the detected sampled reflection signal (hereinafter, it is referred to as a second detection signal 16a) is transmitted to the second end of the first comparator 222.

In some embodiments, the first detection circuit 218 and/or the second detection circuit 220 includes a diode, an inductor and a capacitor. An input of the diode is coupled to an output of a first amplifier 214, an output of the diode is coupled to a first end of the inductor and a first end of the capacitor, and a second end of the inductor and a second end of the capacitor are grounded, to rectify a first amplification signal.

In some embodiments, the detector circuit includes a first amplifier and/or a second amplifier. The first amplifier is coupled to the output of the sampling circuit, receives the sampled transmission signal, is configured to amplify the sampled transmission signal, and is provided with an output coupled to the first comparator. The second amplifier is coupled to the output of the sampling circuit, receives the sampled reflection signal, is configured to amplify the sampled reflection signal, and is provided with an output coupled to the first comparator. At this time, the sampling circuit is connected to the first comparator through the first amplifier and/or the second amplifier.

It should be noted that when the detector circuit includes a detection circuit, the first amplifier and/or the second amplifier is connected to the first comparator through the detection circuit, and the detection circuit may include the first detection circuit and the second detection circuit, which are not elaborated here.

The first amplifier and/or the second amplifier may amplify the sampling signal, so that when the sampling signal is weak, strength of the sampling signal may be enhanced, and then the sampling signal may be further processed.

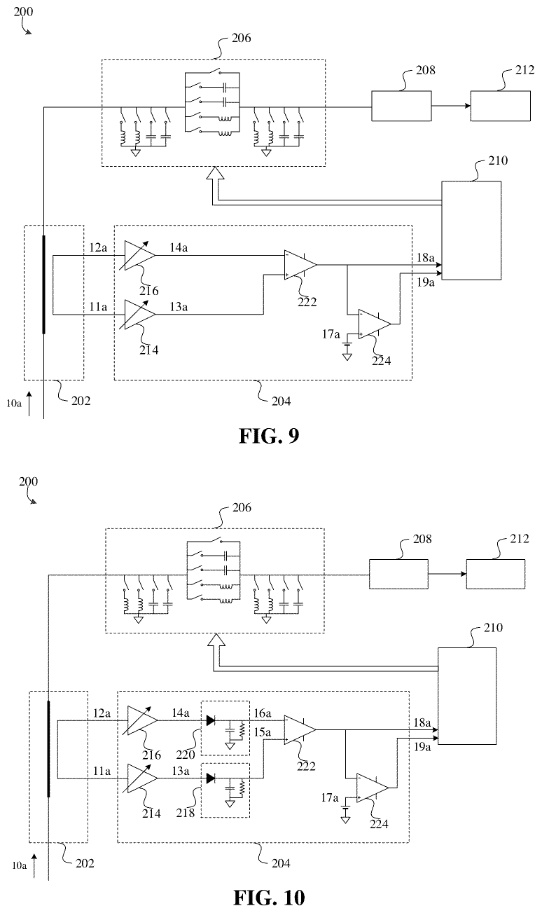

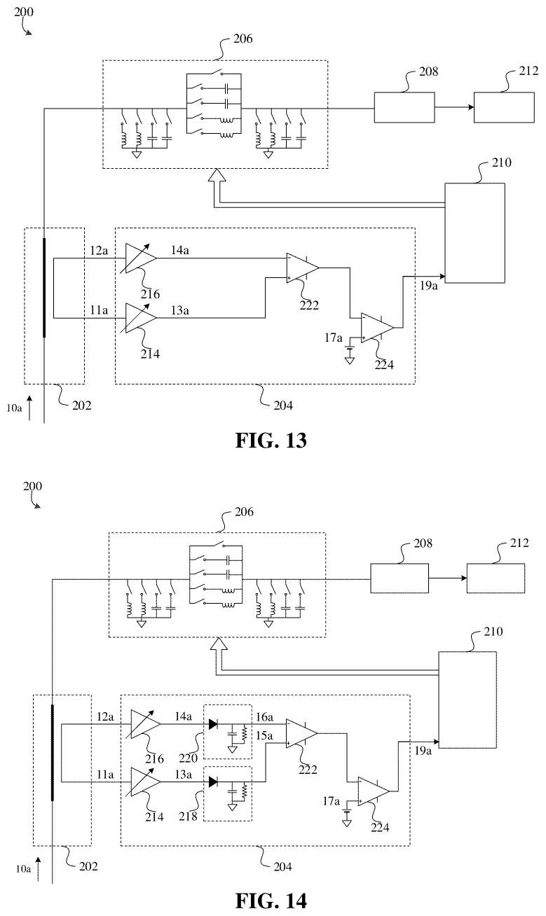

In some embodiments, the detector circuit 204 includes a first amplifier 214, the first amplifier 214 is configured to amplify the sampled transmission signal 11a, the amplified sampled transmission signal (hereinafter, it is referred to as a first amplification signal 13a, and refers to FIG. 5, FIG. 9 or FIG. 13) is transmitted to the first end of the first comparator 222, and the sampled reflection signal 12a is transmitted to the second end of the first comparator 222 (not shown in FIG. 5, FIG. 9 or FIG. 13).

In some embodiments, the detector circuit 204 includes a second amplifier 216, the sampled transmission signal 11a is transmitted to the first end of the first comparator 222 (not shown in FIG. 5, FIG. 9 or FIG. 13), the second amplifier 216 is configured to amplify the sampled reflection signal 12a, and the amplified sampled reflection signal (hereinafter, it is referred to as a second amplification signal 14a, and refers to FIG. 5, FIG. 9 or FIG. 13) is transmitted to the second end of the first comparator 222.

In some embodiments, with reference to FIG. 5, FIG. 9 or FIG. 13, the detector circuit 204 includes a first amplifier 214 and a second amplifier 216. The first amplifier 214 is configured to amplify the sampled transmission signal 11a, and the amplified sampled transmission signal (hereinafter, it is referred to as a first amplification signal 13a) is transmitted to the first end of the first comparator 222. The second amplifier 216 is configured to amplify the sampled reflection signal 12a, and the amplified sampled reflection signal (hereinafter, it is referred to as a second amplification signal 14a) is transmitted to the second end of the first comparator 222.

In some embodiments, gain of the first amplifier is different from that of the second amplifier, to process the sampling signal according to requirements. For example, the gain of the second amplifier acquiring the sampled reflection signal is greater than that of the first amplifier. In other embodiments, the gain of the second amplifier may also be the same as that of the first amplifier.

In some embodiments, the first amplifier and/or the second amplifier is a multi-stage amplifier including multiple amplifiers connected in sequence, to amplify the signal multiple times. In other embodiments, the first amplifier and/or the second amplifier may also be a single-stage amplifier.

In some embodiments, there may also be multiple first amplifiers and/or multiple second amplifiers, and multiple amplifiers have different parameters respectively and may be switched according to parameters such as band of the RF signal, etc.

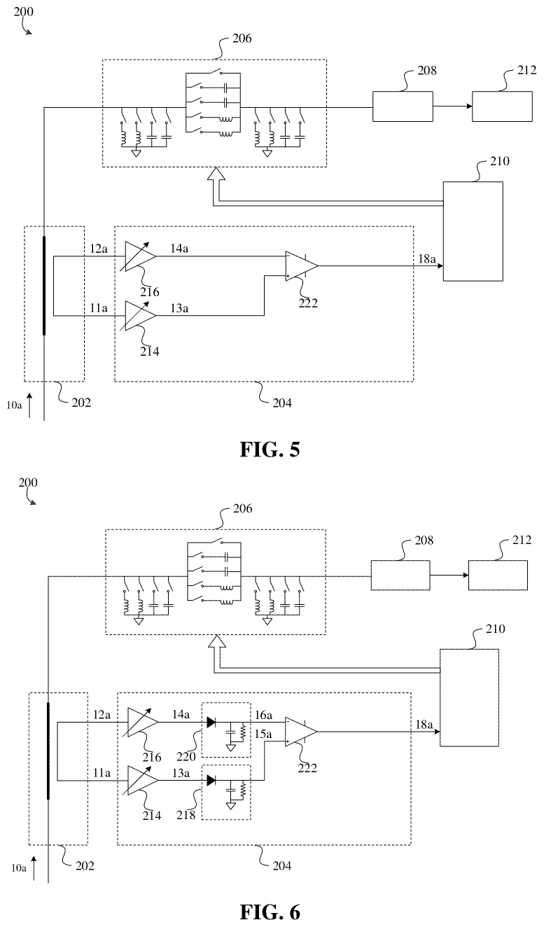

In some embodiments, with reference to FIG. 5, FIG. 6, FIG. 9, FIG. 10, FIG. 13 or FIG. 14, parameters of the first amplifier and/or the second amplifier are adjustable, that is, the first amplifier 214 and/or the second amplifier 216 is an adjustable amplifier, to amplify the sampling signal according to information such as band of the sampling signal, strength of the signal, VSWR, etc.

In some embodiments, the first amplifier 214 and/or the second amplifier 216 is an amplifier with fixed parameters.

In some embodiments, with reference to FIG. 3 to FIG. 14, the adjustment circuit further includes a processor circuit 210. The processor circuit 210 is coupled to the detector circuit 204 and the impedance adjustment circuit 206, and is configured to control on or off of adjustment of the impedance performed by the impedance adjustment circuit 206 according to an output signal from the detector circuit 204, and to control the impedance adjustment circuit 206 to adjust the impedance.

In some embodiments, the output signal from the detector circuit 204 includes a first detection signal 18a and a second detection signal 19a, and the processor circuit 210 acquires the first detection signal and the second detection signal, and controls the impedance adjustment circuit according to the first detection signal and the second detection signal. Specifically, the processor circuit 210 controls adjustment of the impedance performed by the impedance adjustment circuit 206 to be turned on according to the second detection signal 19a, and adjusts the impedance according to the first detection signal 18a; the processor circuit 210 is also configured to control adjustment of the impedance performed by the impedance adjustment circuit 206 to be turned off according to the second detection signal 19a, and the processor does not receive the first detection signal 18a at this time. In this way, it is unnecessary for the processor circuit 210 to be in a state of receiving all the time, which may reduce a data processing amount of the processor circuit 210.

It should be noted that signal processing and control in the above embodiments may be achieved by the processor circuit, for example, comparison of the first detection signal with a preset value, table lookup or other manners are used to control adjustment of the impedance, adjust the gain of the first amplifier and/or the gain of the second amplifier, or the like, which are not elaborated here.

In some embodiments, the processor circuit 210 includes a memory circuit, the memory circuit is configured to store a LUT, and the LUT includes preset adjustment data; the processor circuit 210 is also configured for adjustment of the impedance performed by the impedance adjustment circuit by traversing the preset adjustment data. In some embodiments, the memory circuit may be a Random Access Memory (RAM).

In some embodiments, the impedance adjustment circuit 206 and the aperture tuning circuit 208 are integrated into the same module. In this way, requirements of important indices such as low cost, miniaturization or the like of the adjustment circuit may be met. In other embodiments, the impedance adjustment circuit 206 and the aperture tuning circuit 208 may also be located in different modules respectively.

It should be noted that components/circuits in the above embodiments may be applied to other embodiments, which is not limited in the disclosure; components/circuits used for impedance matching (such as the impedance adjustment circuit 206) may be fully or partially set as adjustable structures.

In several embodiments provided in the disclosure, it should be understood that the disclosed devices and methods may be implemented in other manners. The device embodiments as described above are only schematic, and for example, division of the units is only a logic function division, and there may be other division manners in actual implementations. For example, multiple units or components may be combined or integrated into another system, or some features may be omitted or may not be executed. Furthermore, coupling or direct coupling or communication connection between displayed or discussed components may be indirect coupling or communication connection implemented through some interfaces, of the device or the units, and may be electrical, mechanical or use other forms.

The above units described as separate components may be or may not be physically separated, and components displayed as units may be or may not be physical units, that is, may be located in a place, or may be distributed to multiple network units. Part or all of the units may be selected to achieve the purpose of the solutions in the embodiments according to actual requirements.

Furthermore, each functional unit in the embodiments of the disclosure may be integrated into a processing unit, or each unit may be separately used as a unit, or two or more than two units may be integrated into a unit. The above integrated unit may be implemented in form of hardware or in form of hardware plus software functional units.

It may be understood that “one embodiment” or “an embodiment” mentioned throughout the description means that specific features, structures or characteristics related to the embodiment are included in at least one embodiment of the disclosure. Therefore, “in one embodiment” or “in an embodiment” present throughout the description does not necessarily refer to the same embodiment. Furthermore, these specific features, structures or characteristics may be combined in one or more embodiments in any suitable manner. It should be understood that in various embodiments of the disclosure, sizes of serial numbers of the above processes do not mean a sequence of execution, and the sequence of execution of each process should be determined by its function and internal logic, and should not constitute any limitation on implementation processes of the embodiments of the disclosure. The above serial numbers of the embodiments of the disclosure are only for the purpose of descriptions, and do not represent advantages and disadvantages of the embodiments.

It should be noted that terms “including”, “include” or any other variants thereof in the context are intended to encompass a non-exclusive inclusion, so that a process, method, article or apparatus including a series of elements includes not only those elements, but also other elements which are not explicitly listed, or elements inherent to such process, method, article or apparatus. Without further limitation, an element defined by a statement “including a . . . ” does not preclude presence of additional identical elements in a process, method, article or apparatus including the element.

The above descriptions are only implementations of the disclosure, however, the scope of protection of the disclosure is not limited thereto. Variation or replacement easily conceived by any technician familiar with this technical field within the technical scope disclosed in the disclosure, should fall within the scope of protection of the disclosure.

We claim:

1. An adjustment circuit, connected to an output of a Power Amplifier (PA), the adjustment circuit comprising:
a sampling circuit, connected to the output of the PA, and configured to sample a transmission signal and a reflection signal from the output of the PA, and output the sampled transmission signal and the sampled reflection signal;
a detector circuit, coupled to an output of the sampling circuit, and configured to acquire the sampled transmission signal and the sampled reflection signal, and output a first detection signal according to an amplitude of the sampled transmission signal and an amplitude of the sampled reflection signal;
an impedance adjustment circuit, connected to the detector circuit, and configured to adjust impedance according to the first detection signal, to reduce the reflection signal; and
an aperture tuning circuit, connected to the impedance adjustment circuit.

2. The adjustment circuit of claim 1, wherein the detector circuit comprises:
a first comparator, provided with a first end connected to the sampling circuit and receiving the sampled transmission signal, and a second end connected to the sampling circuit and receiving the sampled reflection signal, wherein the first comparator is configured to compare the amplitude of the sampled transmission signal with the amplitude of the sampled reflection signal and output the first detection signal.

3. The adjustment circuit of claim 2, wherein the impedance adjustment circuit is configured to:
turn on or off adjustment of the impedance according to the first detection signal, and adjust the impedance according to the first detection signal.

4. The adjustment circuit of claim 3, wherein when the first detection signal is less than or equal to a preset value, the impedance adjustment circuit turns on adjustment of the impedance and adjusts the impedance, and when the first detection signal is greater than the preset value, the impedance adjustment circuit turns off adjustment of the impedance; or
when the first detection signal is equal to or greater than a preset value, the impedance adjustment circuit turns on adjustment of the impedance and adjusts the impedance, and when the first detection signal is less than the preset value, the impedance adjustment circuit turns off adjustment of the impedance.

5. The adjustment circuit of claim 2, wherein the detector circuit further comprises:
a second comparator, provided with a first end connected to an output of the first comparator and receiving the first detection signal, and a second end receiving a reference signal, wherein the second comparator is configured to compare the reference signal with the first detection signal and output a second detection signal, and the second detection signal is configured to turn on or off adjustment of the impedance performed by the impedance adjustment circuit.

6. The adjustment circuit of claim 5, wherein when the first detection signal is less than or equal to the reference signal, the impedance adjustment circuit turns on adjustment of the impedance according to the second detection signal, and adjusts the impedance according to the first detection signal,
when the first detection signal is greater than the reference signal, the impedance adjustment circuit turns off adjustment of the impedance.

7. The adjustment circuit of claim 1, wherein the impedance adjustment circuit presets a plurality of impedance combinations, and the impedance adjustment circuit adjusts the impedance by traversal and/or table lookup.

8. The adjustment circuit of claim 2, wherein the detector circuit comprises:
a first detection circuit, provided with an input coupled to the output of the sampling circuit and receiving the sampled transmission signal, and configured to rectify the sampled transmission signal, and provided with an output coupled to the first comparator; and/or
a second detection circuit, provided with an input coupled to the output of the sampling circuit and receiving the sampled reflection signal, and configured to detect the sampled reflection signal, and provided with an output coupled to the first comparator,
the first comparator compares the amplitude of the sampled transmission signal or the detected sampled transmission signal with the amplitude of the sampled reflection signal or the detected sampled reflection signal.

9. The adjustment circuit of claim 2, wherein the detector circuit comprises:
a first amplifier, coupled to the output of the sampling circuit, receiving the sampled transmission signal, configured to amplify the sampled transmission signal, and provided with an output coupled to the first comparator; and/or
a second amplifier, coupled to the output of the sampling circuit, receiving the sampled reflection signal, configured to amplify the sampled reflection signal, and provided with an output coupled to the first comparator,
the first comparator compares the amplitude of the sampled transmission signal or the amplified sampled transmission signal with the amplitude of the sampled reflection signal or the amplified sampled reflection signal.

10. The adjustment circuit of claim 9, wherein parameters of the first amplifier and/or the second amplifier are adjustable.

11. The adjustment circuit of claim 1, wherein the impedance adjustment circuit comprises:
a first branch, provided with a first end connected to the sampling circuit, and a second end which is grounded;
a second branch, provided with a first end connected to the aperture tuning circuit, and a second end which is grounded; and
a third branch, provided with a first end and a second end connected to the first end of the first branch and the first end of the second branch respectively.

12. The adjustment circuit of claim 11, wherein at least one of the first branch, the second branch or the third branch is provided with a plurality of inductors and/or capacitors connected in parallel, and a switch is connected in series with at least one path of the parallel circuit.

13. The adjustment circuit of claim 1, wherein the impedance adjustment circuit and the aperture tuning circuit are integrated into the same module.
